(19) United States
(12) Patent Application Publication
(10) Pub. No.: US 2026/0262542 A1
(43) Pub. Date: Sep. 3, 2026

(54) STACKED TYPE SEMICONDUCTOR PACKAGE

(71) Applicant: SK hynix Inc., Icheon-si Gyeonggi-do (KR)

(72) Inventor: In Soo LEE, Icheon-si Gyeonggi-do (KR)

(73) Assignee: SK hynix Inc., Icheon-si Gyeonggi-do (KR)

(21) Appl. No.: 19/210,814

(22) Filed: May 16, 2025

(30) Foreign Application Priority Data
Feb. 28, 2025 (KR) 10-2025-0027027

(51) Int. Cl. H10W 90/00; H10W 72/59; H10W 72/90; H10W 90/24

(52) U.S. Cl. CPC H10W 90/00; H10W 72/59; H10W 72/9445; H10W 90/24; H10W 90/724; H10W 90/752; H10W 90/754

(57) ABSTRACT

A semiconductor package includes a substrate on which a first substrate pad array and a second substrate pad array are formed; and a plurality of semiconductor dies each including a first die pad array and a second die pad array, the plurality of semiconductor dies stacked on the substrate in a stack. A first semiconductor die of the plurality of semiconductor dies is stacked such that the first die pad array and the second die pad array of the first semiconductor die face the first substrate pad array and the second substrate pad array, respectively, and the semiconductor dies, except for the first semiconductor die, are stacked in an orientation opposite to an orientation of the first semiconductor die.

The present application claims priority under 35 U.S.C. §119(a) to Korean application number 10-2025-0027027 filed on February 28, 2025, in the Korean Intellectual Property Office, which application is incorporated herein by reference in its entirety.

### BACKGROUND

### 1. Technical Field

Various embodiments generally relate to a semiconductor circuit, including but not limited to a stacked type semiconductor package using a wire bonding structure.

### 2. Related Art

Semiconductor package assembly technology provides operational reliability of the semiconductor die by protecting the semiconductor die, in which an integrated circuit is formed, from the external environment and facilitating the semiconductor die to be easily mounted on the substrate. In the package assembly technology, a wire bonding method using a conductive wire is one method used to connect the semiconductor die and the substrate.

The wire bonding method is the most common connection method and is suitable for use in a stacked type structure. When the quantity of stacked semiconductor dies increases, the length of the wire also increases, which causes a longer signal transmission path, thereby deteriorating electrical characteristics and increasing the package size.

### SUMMARY

In an embodiment, a semiconductor package may include a substrate and a plurality of semiconductor dies. A first substrate pad array and a second substrate pad array may be formed on the substrate. The plurality of semiconductor dies each may include a first die pad array and a second die pad array, and the plurality of semiconductor dies may be stacked on the substrate. A first semiconductor die of the plurality of semiconductor dies may be stacked such that the first die pad array and the second die pad array of the first semiconductor die face the first substrate pad array and the second substrate pad array, respectively. The semiconductor dies, except for the first semiconductor die, may be stacked in an orientation opposite to an orientation of the first semiconductor die.

In an embodiment, a semiconductor package may include a substrate, a first semiconductor die, a second semiconductor die, a third semiconductor die, and a plurality of conductive wires. The substrate may include a first substrate pad array and a second substrate pad array. The first semiconductor die may have a first surface on which a first die pad array and a second die pad array are formed, the first die pad array may be electrically connected to the first substrate pad array through a first bump array, and the second die pad array may be electrically connected to the second substrate pad array through a second bump array. The second semiconductor die may have a first surface on which a first die pad array and a second die pad array are formed, and the second semiconductor die may be stacked on the first semiconductor die such that a second surface of the second semiconductor die faces a second surface of the first semiconductor die. The third semiconductor die may have a first surface on which a first die pad array and a second die pad array are formed, and the third semiconductor die may be stacked on the second semiconductor die such that a second surface of the third semiconductor die faces the first surface of the second semiconductor die. The plurality of conductive wires may be configured to electrically connect the second die pad array of the second semiconductor die, the second die pad array of the third semiconductor die, and the second substrate pad array.

In an embodiment, a semiconductor package may include a substrate, a plurality of semiconductor dies, and a plurality of conductive wires. A substrate pad array may be formed on the substrate. The plurality of semiconductor dies may be stacked on the substrate, and each of the plurality of semiconductor dies may be configured to have a first die pad array, a second die pad array, and at least one third die pad array formed thereon. The plurality of conductive wires may be configured to electrically connect the substrate pad array, at least one third die pad array of a topmost one of the plurality of semiconductor dies, and the first die pad array of the topmost semiconductor die.

### BRIEF DESCRIPTION OF THE DRAWINGS

FIG. 1 is a cross-sectional view illustrating a semiconductor package according to an embodiment of the present disclosure.

FIG. 2 is a perspective view illustrating a portion of the semiconductor package according to an embodiment of the present disclosure.

FIG. 3 is a cross-sectional view illustrating a semiconductor package according to an embodiment of the present disclosure.

FIG. 4 is a perspective view illustrating a portion of the semiconductor package according to an embodiment of the present disclosure.

FIG. 5 is a perspective view illustrating a subset of pads of the semiconductor package according to an embodiment of the present disclosure.

FIG. 6 is a diagram illustrating pad connections according to an embodiment of the present disclosure.

FIG. 7 is a diagram illustrating an internal circuit according to an embodiment of the present disclosure.

FIG. 8 is a diagram illustrating a configuration of a first switching circuit according to an embodiment of the present disclosure.

FIG. 9 is a table illustrating data during an operation of the switching circuit according to an embodiment of the present disclosure.

FIGS. 10 and 11 are diagrams illustrating semiconductor packages according to embodiments of the present disclosure.

### DETAILED DESCRIPTION

Various embodiments can reduce the size of the semiconductor package and improve signal transmission quality by reducing loading related to delivering signals to the semiconductor die from outside the package.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example.

Terms such as “topmost,” “bottom,” “above,” “under,” “on,” “side,” “lowermost,” “high,” “low,” “front,” “rear,” “right,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

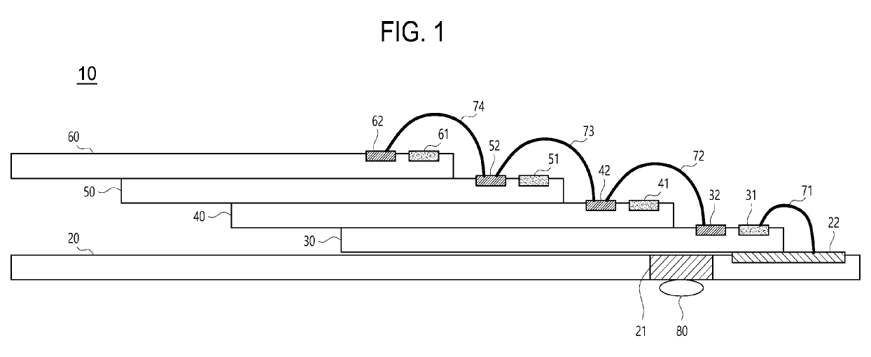

FIG. 1 is a diagram illustrating a semiconductor package 10 according to an embodiment of the present disclosure.

Referring to FIG. 1, the semiconductor package 10 includes a substrate 20, a plurality of semiconductor dies 30, 40, 50, and 60, and a plurality of conductive wire arrays 71 to 74. FIG. 1 is an example in which four semiconductor dies are stacked on the substrate 20, and the quantity of stacked semiconductor dies may vary depending on the total storage capacity of the package or the storage capacity of each semiconductor die.

The substrate 20 includes a first substrate pad array 21 and a second substrate pad array 22. The first substrate pad array 21 is electrically connected outside of the package through a bump array 80.

The plurality of semiconductor dies 30, 40, 50, and 60 are stacked on the substrate 20. The plurality of semiconductor dies 30, 40, 50, and 60 may be configured substantially identical or similar to each other. Each of the plurality of semiconductor dies 30, 40, 50, and 60 includes first die pad arrays 31, 41, 51, 61 and second die pad arrays 32, 42, 52, 62 formed on a first surface, for example, a front surface. A “front” surface of a semiconductor die is a surface on which one or more pads are disposed, and a “rear” surface of a semiconductor die is a surface on which no pads are disposed. The front surface of a semiconductor die is on an opposite side of the rear surface of the semiconductor die. The first semiconductor die 30 includes a first die pad array 31 and a second die pad array 32. The second semiconductor die 40 includes a first die pad array 41 and a second die pad array 42. The third semiconductor die 50 includes a first die pad array 51 and a second die pad array 52. The fourth semiconductor die 60 includes a first die pad array 61 and a second die pad array 62.

The plurality of semiconductor dies 30, 40, 50, and 60 may be stacked offset from each other or in a step-wise manner such that each first die pad array and second die pad array is exposed after the semiconductor dies 30, 40, 50, and 60 are stacked.

A first conductive wire array 71 electrically connects the second substrate pad array 22 and the first die pad array 31 of the first semiconductor die 30. A second conductive wire array 72 electrically connects the second die pad array 32 of the first semiconductor die 30 and a second die pad array 42 of the second semiconductor die 40. A third conductive wire array 73 electrically connects the second die pad array 42 of the second semiconductor die 40 and the second die pad array 52 of the third semiconductor die 50. A fourth conductive wire array 74 electrically connects the second die pad array 52 of the third semiconductor die 50 and the second die pad array 62 of the fourth semiconductor die 60.

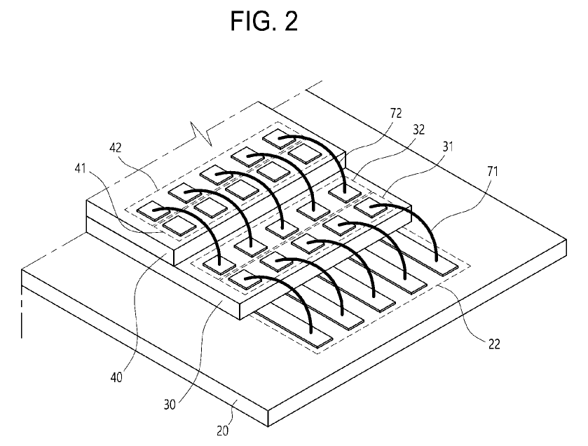

FIG. 2 is a perspective view illustrating a portion of semiconductor package 10, for example, as shown in FIG. 1. FIG. 2 illustrates a subset of pads included in the second substrate pad array 22, the first die pad arrays 31, 41, and the second die pad arrays 32, 42 of FIG. 1.

Referring to FIG. 2, pads of the second substrate pad array 22 are connected one-to-one to pads of the first die pad array 31 of the first semiconductor die 30 through conductive wires of the first conductive wire array 71. Pads of the second die pad array 32 of the first semiconductor die 30 are connected one-to-one to pads of the second die pad array 42 of the second semiconductor die 40 through conductive wires of the second conductive wire array 72.

Referring to FIG. 1 and FIG. 2, among the plurality of semiconductor dies 30, 40, 50, and 60 stacked on the substrate 20, the lowermost semiconductor die, that is, the first semiconductor die 30, operates as a master, and the semiconductor dies 40, 50, and 60, except for the first semiconductor die, operate as slaves. The first semiconductor die 30, which operates as a master, receive signals from the outside of the semiconductor package 10 through the substrate 20 and transfers the signals to the second to fourth semiconductor dies 40, 50, and 60 that operate as slaves.

For example, signals transmitted from a device outside the semiconductor package 10 are transmitted to the first die pad array 31 of the first semiconductor die 30 through the bump array 80, the first substrate pad array 21, the second substrate pad array 22, and the first conductive wire array 71. The signals transmitted to the first semiconductor die 30 are transmitted to the semiconductor dies 40, 50, and 60 through the second die pad array 32, the second conductive wire array 72 to the fourth conductive wire array 74, and the second die pad arrays 42, 52, and 62.

Signals inside the semiconductor package 10 are transmitted to a device outside the semiconductor package 10 through the bump array 80 via the same electrical path.

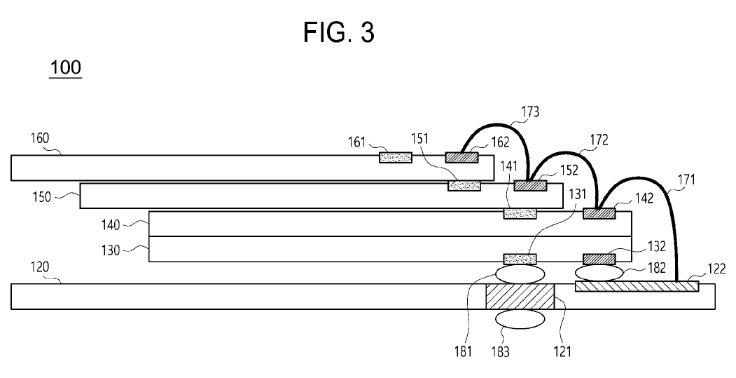

FIG. 3 is a diagram illustrating semiconductor package 100 according to an embodiment of the present disclosure.

Referring to FIG. 3, the semiconductor package 100 includes a substrate 120, a plurality of semiconductor dies 130, 140, 150, and 160, and a plurality of conductive wire arrays 171 to 173.

A first substrate pad array 121 and a second substrate pad array 122 are formed on a first surface, for example, a top or front surface, of the substrate 120, where top is a reference within the drawing. The first substrate pad array 121 is formed at a first distance in a first outward direction, for example, toward the right side of FIG. 3, from the center of the substrate 120. The second substrate pad array 122 is formed at a second distance in the first outward direction from the first substrate pad array 121. The first substrate pad array 121 is electrically connected to an external device of the semiconductor package 100 through an external bump array 183 to transmit and receive signals.

Each of the plurality of semiconductor dies 130, 140, 150, and 160 includes first die pad arrays 131, 141, 151, 161 and second die pad arrays 132, 142, 152, 162 formed on a first surface, for example, a top or front surface, and are stacked on the substrate 120. The plurality of semiconductor dies 130, 140, 150, and 160 may be configured substantially identical or similar to each other.

Among the plurality of semiconductor dies 130, 140, 150, and 160, the lowermost semiconductor die 130 is stacked such that a first die pad array 131 and a second die pad array 132 face the first substrate pad array 121 and the second substrate pad array 122, respectively. The semiconductor dies 140, 150, and 160, except for the lowermost semiconductor die 130, are stacked in an orientation opposite to the orientation of the lowermost semiconductor die 130. A front surface of the lowermost semiconductor die 130 is stacked to face the front surface of the substrate 120. The second surface, such as the bottom or rear surface, of each of the semiconductor dies 140, 150, and 160, except for the lowermost semiconductor die 130, is stacked to face the top or front surface of the substrate 120, where bottom is a reference within the drawing.

The plurality of semiconductor dies 130, 140, 150, and 160 includes a first semiconductor die 130, a second semiconductor die 140, a third semiconductor die 150, and a fourth semiconductor die 160, sequentially numbered in the stacking order on the substrate 120.

The first die pad array 131 of the first semiconductor die 130 is electrically connected to the first substrate pad array 121 through a first bump array 181. The second die pad array 132 of the first semiconductor die 130 is electrically connected to the second substrate pad array 122 through a second bump array 182.

A first die pad array 141 and a second die pad array 142 are formed on a top or front surface of the second semiconductor die 140 that is stacked on the first semiconductor die 130 such that the bottom or rear surface of the second semiconductor die 140 faces the top or rear surface of the first semiconductor die 130.

A first die pad array 151 and a second die pad array 152 are formed on the top or front surface of the third semiconductor die 150 that is stacked on the second semiconductor die 140 such that the bottom or rear surface of the third semiconductor die 150 faces the top or front surface of the second semiconductor die 140.

A first die pad array 161 and a second die pad array 162 formed on the top or front surface of the fourth semiconductor die 160 that is stacked on the third semiconductor die 150 such that the bottom or rear surface of the fourth semiconductor die 160 faces the top or front surface of the third semiconductor die 150.

The plurality of conductive wire arrays 171 to 173 includes a first conductive wire array 171, a second conductive wire array 172, and a third conductive wire array 173. The first conductive wire array 171 electrically connects the second substrate pad array 122 and the second die pad array 142 of the second semiconductor die 140. The second conductive wire array 172 electrically connects the second die pad array 142 of the second semiconductor die 140 and the second die pad array 152 of the third semiconductor die 150. The third conductive wire array 173 electrically connects the second die pad array 152 of the third semiconductor die 150 and the second die pad array 162 of the fourth semiconductor die 160.

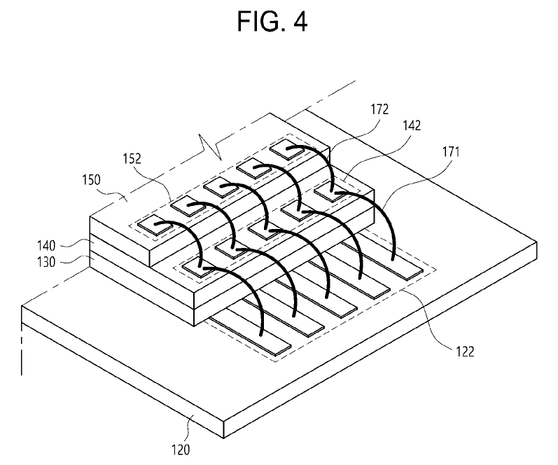

FIG. 4 is a perspective view illustrating a portion of semiconductor package 100, for example, as shown in FIG. 3. FIG. 4 illustrates a subset of pads included in the second substrate pad array 122 and the second die pad arrays 142, 152, for example, as shown in FIG. 3.

Referring to FIG. 4, the top or rear surface and the bottom or front surface of the first semiconductor die 130 are not visible because the first semiconductor die 130is stacked such that the first die pad array 131 and the second die pad array 132 face the first substrate pad array 121 and the second substrate pad array 122, respectively.

Pads of second substrate pad array 122 are connected one-to-one to pads of the second die pad array 142 of second semiconductor die 140 through conductive wires of the first conductive wire array 171. The pads of second die pad array 142 of second semiconductor die 140 are connected one-to-one to pads of second die pad array 152 of third semiconductor die 150 through conductive wires of the second conductive wire array 172.

In the semiconductor package 100 of FIG. 4, the first semiconductor die 130 is electrically connected to the substrate 120 without a conductive wire, and the outermost pad arrays of second semiconductor die 140, the third semiconductor die 150, and the fourth semiconductor die 160. For example, the second die pad arrays 142, 152, 162 are electrically connected to the substrate 120 through the pads of second substrate pad array 122 and the plurality of conductive wire arrays 171 to 173. Because first die pad arrays 131, 141, 151, 161 are not exposed to the outside environment, the plurality of semiconductor dies 130, 140, 150, and 160 may be stacked on substrate 120 without exposing first die pad arrays, thereby facilitating reduced package size.

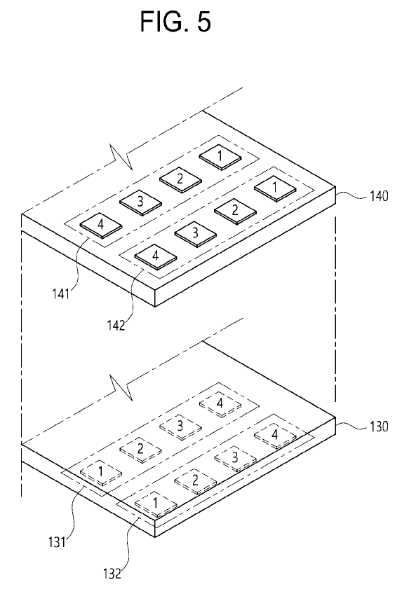

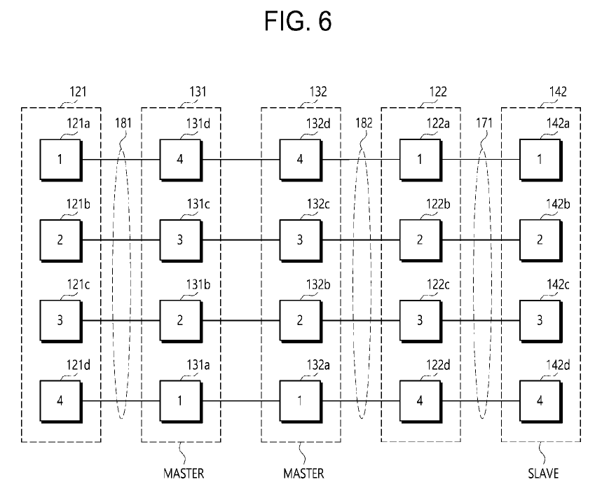

FIG. 5 is a perspective view illustrating a subset of the pads of semiconductor package 100, for example, as shown in FIG. 3, and FIG. 6 is a diagram illustrating pad connections, for example, according to FIG. 3. FIG. 6 illustrates a subset of pads included in the first substrate pad array 121, the second substrate pad array 122, the first die pad array 131, and the second die pad arrays 132, 142.

Referring to FIG. 5, the first semiconductor die 130 located at the lowermost position in the stack has a top or front surface, where the first die pad array 131 and the second die pad array 132 are formed, that faces the substrate 120, whereas the second semiconductor die 140, the third semiconductor die 150, and the fourth semiconductor die 160 have bottom or rear surfaces, where the first die pad arrays 141, 151, 161 and the second die pad arrays 142, 152, 162 are not formed, that face the substrate 120.

Because the plurality of semiconductor dies 130, 140, 150, and 160 are configured substantially identical or similar to each other, transmitted signals are assigned according to or based on pad number. Because the first semiconductor die 130 is stacked in the opposite orientation from the orientations of the second semiconductor die 140, the third semiconductor die 150, and the fourth semiconductor die 160, the sequence or order of corresponding pad numbers of the first semiconductor die 130 is different from the sequence or order of corresponding pad numbers for the other semiconductor dies 140, 150, and 160.

Pads of the first die pad array 131 and the second die pad array 132 of the first semiconductor die 130 transmit the same sequence of signals, and pads of the first die pad array 141 and the second die pad array 142 of the second semiconductor die 140 also transmit the same sequence of signals. Pads numbered 1, 2, 3, and 4 of the second die pad array 132 of the first semiconductor die 130 are connected to pads numbered 4, 3, 2, and 1 of the second die pad array 142 of the second semiconductor die 140, respectively, through the second conductive wire array 172, such that signals are transmitted in a different sequence than intended.

Referring to FIG. 6, signals transmitted at pads 121a, 121b, 121c, 121d (numbered 1 to 4) of the first substrate pad array 121 are transmitted through the first bump array 181 to pads 131d, 131c, 131b, 131a (numbered 4 to 1), respectively, of the first die pad array 131 of the first semiconductor die 130, which operates as a master. Signals having a different sequence are transmitted to the pads 4 to 1 of the first die pad array 131 than are transmitted at the first substrate pad array 121 (numbered 1 to 4).

The signals transmitted through the pads 131d, 131c, 131b, 131a of the first die pad array 131 of the first semiconductor die 130 are transmitted to pads 132d, 132c, 132b, 132a of the second die pad array 132 through a predetermined signal processing procedure via an internal signal processing circuit (not shown). The word “predetermined” as used with respect to a signal control operation or procedure includes a signal processing procedure determined prior to the use in a process or algorithm.

The signals transmitted through the pads 132d, 132c, 132b, 132a of the second die pad array 132 are transmitted to pads 122a, 122b, 122c, 122d of the second substrate pad array 122 of the substrate 120 through the second bump array 182.

The signals transmitted to the pads 122a, 122b, 122c, 122d of the second substrate pad array 122 are transmitted to pads 142a, 142b, 142c, 142d (numbered 1 to 4) of the second die pad array 142 of the second semiconductor die 140, which operates as a slave, through the first conductive wire array 171.

As described with reference to FIG. 5 and FIG. 6, signals transmitted from outside the semiconductor package 100 are transmitted to the lowermost semiconductor die, which operates as a master, in a changed or altered sequence. Accordingly, the plurality of semiconductor dies included in the semiconductor package 100 include switching circuits configured to change, based on a master identification signal, the sequence of signals transmitted between pads of the first die pad array and pads of the second die pad array.

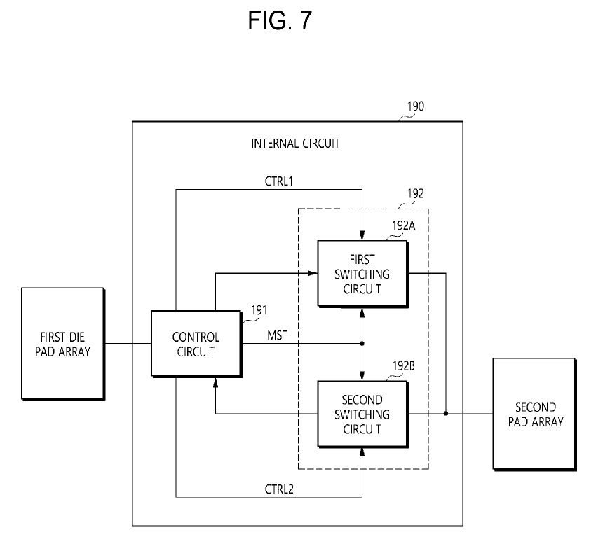

FIG. 7 is a diagram illustrating an internal circuit 190 according to an embodiment of the present disclosure.

Referring to FIG. 7, the internal circuit 190 is connected between a first die pad array and a second die pad array. The internal circuit 190 is a circuit configured to perform signal processing and control related to signal input and output of a semiconductor die. The internal circuit 190 includes a control circuit 191 and a switching circuit 192.

The control circuit 191 generates a master identification signal MST at a corresponding logic level according to stacking position information. The control circuit 191 generates a plurality of control signals CTRL1 and CTRL2 based on the master identification signal MST and a read/write operation status. The control circuit 191 receives signals transmitted on the first die pad array and performs a predetermined signal control operation to provide the signals to the switching circuit 192. The control circuit 191 receives signals transmitted through the second die pad array and the switching circuit 192 and performs a predetermined signal control operation.

Among the plurality of semiconductor dies 130, 140, 150, and 160, a semiconductor die operating as a master and a semiconductor die operating as a slave have different logic levels for the master identification signal MST. A logic level of the master identification signal MST is determined according to stacking position information generated internally depending on the stacking order of the semiconductor die. An embodiment of the present disclosure shown in FIG. 3 illustrates an example in which the lowermost semiconductor die operates as a master. The lowermost semiconductor die, which operates as a master, has the master identification signal MST at a first logic level, for example, a logic high level, because the lowermost semiconductor die is stacked on the substrate 120, and semiconductor dies stacked above the lowermost semiconductor die, which operate as slaves, have the master identification signal MST at a second logic level, for example, a logic low level.

The control circuit 191 generates the control signals CTRL1 and CTRL2 as 0 and 1, respectively, when the master identification signal MST is 0 and a write operation is performed. The control circuit 191 generates the control signals CTRL1 and CTRL2 as 1 and 0, respectively, when MST is 0 and a read operation is performed. The control circuit 191 generates the control signals CTRL1 and CTRL2 as 1 and 0, respectively, when MST is 1 and a write operation is performed. The control circuit 191 generates the control signals CTRL1 and CTRL2 as 0 and 1, respectively, when MST is 1 and a read operation is performed.

The switching circuit 192 includes a first switching circuit 192A and a second switching circuit 192B.

The first switching circuit 192A generates output signals by multiplexing input signals, for example, signals transmitted through the first die pad array via the control circuit 191, according to the first control signal CTRL1 and the master identification signal MST and transmits the output signals to the second die pad array. The master identification signal MST is at a logic high level for a semiconductor die operating as a master and at a logic low level for a semiconductor die operating as a slave. The first switching circuit 192A generates output signals by changing the sequence of the input signals when the master identification signal MST is at a logic high level. The first switching circuit 192A generates output signals without changing the sequence of the input signals when the master identification signal MST is at a logic low level. The first switching circuit 192A operates in response to activation of the first control signal CTRL1 and stops operation in response to deactivation of the first control signal CTRL1.

The second switching circuit 192B generates output signals by multiplexing input signals, for example, signals transmitted through the second die pad array, according to the master identification signal MST and transmits the output signals to the control circuit 191. The second switching circuit 192B generates output signals by changing the sequence of the signals transmitted through pads of the second die pad array when the master identification signal MST is at a logic high level. The second switching circuit 192B generates output signals without changing the sequence of the signals transmitted to the pads of the second die pad array when the master identification signal MST is at a logic low level. The second switching circuit 192B operates in response to activation of the second control signal CTRL2 and stops operation in response to deactivation of the second control signal CTRL2.

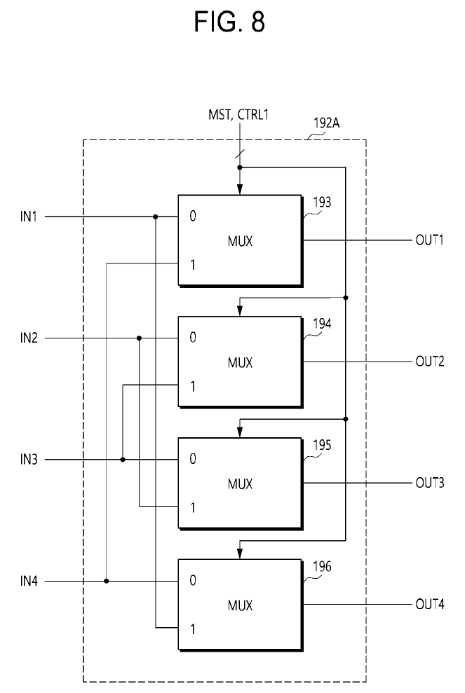

FIG. 8 is a diagram illustrating a configuration of the first switching circuit 192A, for example, as shown in FIG. 7.

Referring to FIG. 8, the first switching circuit 192A includes a plurality of multiplexers 193 to 196. The plurality of multiplexers 193 to 196 operates to change the input signal order or sequence when the first control signal CTRL1 is activated and does not change the input signal order by passing the input signals through with an unchanged order or sequence when the first control signal CTRL1 is deactivated. A first multiplexer 193 selects a first input signal IN1 to generate a first output signal OUT1 when the master identification signal MST is at a logic low level and selects a fourth input signal IN4 to generate the first output signal OUT1 when the master identification signal MST is at a logic high level. A second multiplexer 194 selects a second input signal IN2 to generate a second output signal OUT2 when the master identification signal MST is at a logic low level and selects a third input signal IN3 to generate the second output signal OUT2 when the master identification signal MST is at a logic high level. A third multiplexer 195 selects the third input signal IN3 to generate a third output signal OUT3 when the master identification signal MST is at a logic low level and selects the second input signal IN2 to generate the third output signal OUT3 when the master identification signal MST is at a logic high level. A fourth multiplexer 196 selects the fourth input signal IN4 to generate a fourth output signal OUT4 when the master identification signal MST is at a logic low level and selects the first input signal IN1 to generate the fourth output signal OUT4 when the master identification signal MST is at a logic high level. The first input signals IN1 to the fourth input signal IN4 may be provided by the control circuit 191.

The second switching circuit 192B is configured substantially identically or similarly to the first switching circuit 192A, except that the first input signal IN1 to fourth input signal IN4 are signals transmitted through corresponding pads of the second die pad array and operation is controlled by activation and deactivation of the second control signal CTRL2.

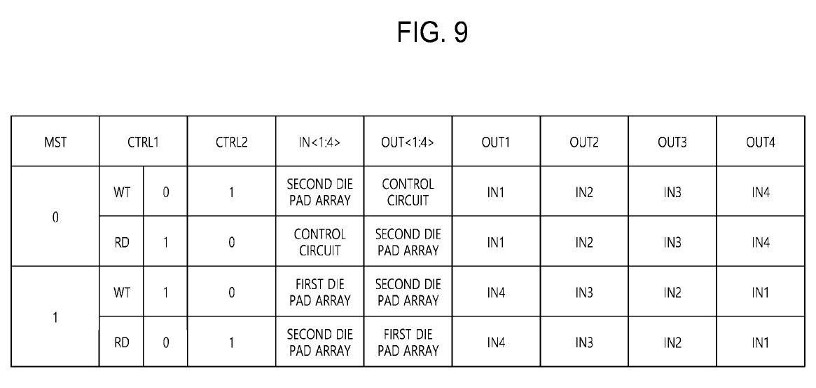

FIG. 9 is a table illustrating data during an operation of the switching circuit 192, for example, as shown in FIG. 7.

Referring to FIG. 7 to FIG. 9, the operation of the switching circuit 192 is described. Operation of the switching circuit 192 is described based on a semiconductor die operating as a slave. When the semiconductor die operates as a slave, the master identification signal MST is at 0or logic low level.

During a write operation WT in which a signal is input from outside the semiconductor package 100, the control circuit 191 outputs the first control signal CTRL1 as 0or logic low level and the second control signal CTRL2 as 1or logic high level.

When the second control signal CTRL2 is 1, the second switching circuit 192B is activated and switches input signals, and when the first control signal CTRL1 is 0, the first switching circuit 192A does not switch input signals or passes input signals through without change.

The second switching circuit 192B receives the input signals IN1 to IN4 through the second die pad array. When the master identification signal MST is 0, the second switching circuit 192B generates output signals OUT1 to OUT4 without changing the sequence of the input signals IN1 to IN4. The output signals OUT1 to OUT4 are transmitted to the control circuit 191.

During a read operation RD in which a signal is output from inside the semiconductor package 100, the control circuit 191 outputs the first control signal CTRL1 as 1 and the second control signal CTRL2 as 0.

When the first control signal CTRL1 is 1, the first switching circuit 192A is activated, and when the second control signal CTRL2 is 0, the second switching circuit 192B is deactivated.

The first switching circuit 192A receives the input signals IN1 to IN4 from the control circuit 191. When the master identification signal MST is 0, the first switching circuit 192A generates the output signals OUT1 to OUT4 without changing the sequence of the input signals IN1 to IN4. The output signals OUT1 to OUT4 are transmitted to the second die pad array.

The operation of the switching circuit 192 is described based on a semiconductor die operating as a master.

When the semiconductor die operates as a master, the master identification signal MST is at 1.

During a write operation WT, the control circuit 191 outputs the first control signal CTRL1 as 1 and the second control signal CTRL2 as 0.

When the first control signal CTRL1 is 1, the first switching circuit 192A is activated, and when the second control signal CTRL2 is 0, the second switching circuit 192B is deactivated.

The first switching circuit 192A receives the input signals IN1 to IN4 from the control circuit 191 via the first die pad array. When the master identification signal MST is 1, the first switching circuit 192A generates the output signals OUT1 to OUT4 by changing the sequence of the input signals IN1 to IN4 to the sequence IN4, IN3, IN2, and IN1. The output signals OUT1 to OUT4 are transmitted to the second die pad array.

During a read operation RD, the control circuit 191 outputs the first control signal CTRL1 as 0 and the second control signal CTRL2 as 1.

When the second control signal CTRL2 is 1, the second switching circuit 192B is activated, and when the first control signal CTRL1 is 0, the first switching circuit 192A stops operating.

The second switching circuit 192B receives the input signals IN1 to IN4 through the second die pad array. When the master identification signal MST is 1, the second switching circuit 192B generates the output signals OUT1 to OUT4 by changing the sequence of the input signals IN1 to IN4 to sequence IN4, IN3, IN2, and IN1. The output signals OUT1 to OUT4 are transmitted to the control circuit 191 and to the first die pad array.

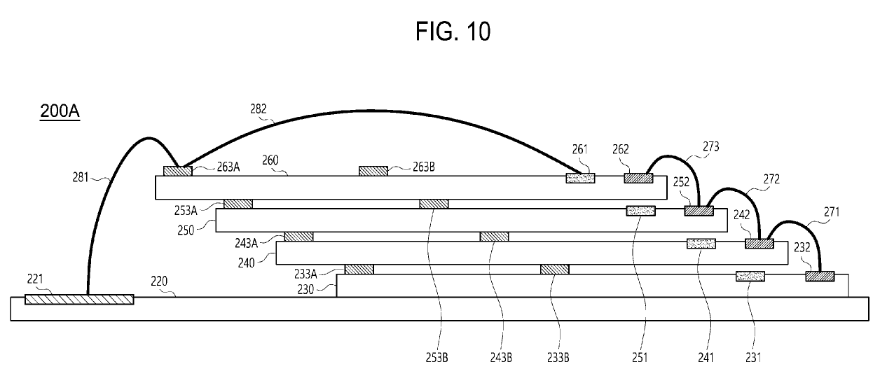

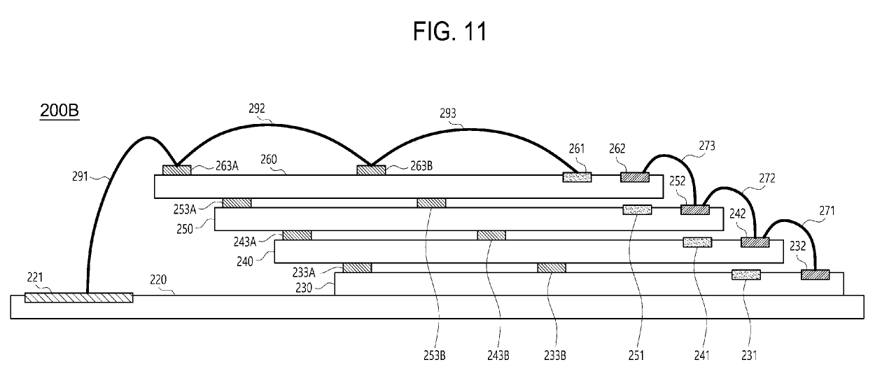

FIG. 10 and FIG. 11 are diagrams illustrating semiconductor packages 200A and 200B, respectively, according to embodiments of the present disclosure.

Referring to FIG. 10, the semiconductor package 200A includes a substrate 220, a plurality of semiconductor dies 230, 240, 250, and 260, and a plurality of conductive wire arrays 271 to 273, 281, and 282.

A substrate pad array 221 is formed on the substrate 220.

The plurality of semiconductor dies 230, 240, 250, and 260 are stacked on the substrate 220.

First die pad arrays 231, 241, 251, 261, second die pad arrays 232, 242, 252, 262, and at least one third die pad array 233A, 233B, 243A, 243B, 253A, 253B, 263A, 263B are formed on a first surface, for example, a top or front surface, of each of the semiconductor dies 230, 240, 250, and 260, respectively.

Among the plurality of semiconductor dies 230, 240, 250, and 260, one of the semiconductor dies operates as a master and the others operate as slaves. FIG. 10 and FIG. 11 illustrate examples in which the topmost or outermost semiconductor die operates as a master.

The plurality of semiconductor dies 230, 240, 250, and 260 includes a first semiconductor die 230, a second semiconductor die 240, a third semiconductor die 250, and a fourth semiconductor die 260, assigned in order of stacking on the substrate 220. The first to fourth semiconductor dies 230, 240, 250, and 260 may be configured substantially identically or similarly to each other.

A first die pad array 231, a second die pad array 232, and third die pad arrays 233A and 233B are formed on the top or front surface of the first semiconductor die 230. A first die pad array 241, a second die pad array 242, and third die pad arrays 243A and 243B are formed on the top or front surface of the second semiconductor die 240. A first die pad array 251, a second die pad array 252, and third die pad arrays 253A and 253B are formed on the top or front surface of the third semiconductor die 250. A first die pad array 261, a second die pad array 262, and third die pad arrays 263A and 263B are formed on the top or front surface of the fourth semiconductor die 260. The substrate pad array 232 is formed at a periphery of the substrate 220, for example, in a first direction

A first conductive wire array 271 electrically connects the second die pad array 232 of the first semiconductor die 230 and the second die pad array 242 of the second semiconductor die 240. A second conductive wire array 272 electrically connects the second die pad array 242 of the second semiconductor die 240 and the second die pad array 252 of the third semiconductor die 250. A third conductive wire array 273 electrically connects the second die pad array 252 of the third semiconductor die 250 and the second die pad array 262 of the fourth semiconductor die 260. A fourth conductive wire array 281 may electrically connect the substrate pad array 221 and the outermost third die pad array 263A among the third die pad arrays 263A and 263B of the fourth semiconductor die 260, which is the topmost semiconductor die operating as a master. A fifth conductive wire array 282 electrically connects the third die pad array 263A and the first die pad array 261 of the fourth semiconductor die 260.

In the semiconductor package 200A of FIG. 10, the second die pad arrays of the first to fourth semiconductor dies 230, 240, 250, and 260 are connected, and the first die pad array 261 of the fourth semiconductor die 260, which is the topmost die, is electrically connected to the substrate 220 through the third die pad array 263A. Therefore, the plurality of semiconductor dies 230, 240, 250, and 260 can be stacked on the substrate 220 without exposing the first die pad arrays to the external environment, thereby reducing package size.

Referring to FIG. 11, the semiconductor package 200B includes the substrate 220, the plurality of semiconductor dies 230, 240, 250, and 260, and a plurality of conductive wire arrays 271 to 273, 291, 292, and 293.

The semiconductor package 200A described with reference to FIG. 10 illustrates an example in which the substrate pad array 221 is connected to the first die pad array 261 of the topmost semiconductor die or the fourth semiconductor die 260, using the fourth conductive wire array 281 and the fifth conductive wire array 282. Although targeted signal transmission quality may be achieved by directly connecting the third die pad array 263A and the first die pad array 261 of the fourth semiconductor die 260 using the fifth conductive wire array 282, signal quality degradation may occur due to various environmental factors such as characteristics of the conductive wire, characteristics of the semiconductor die, and package design.

The semiconductor package 200B according to an embodiment of the present disclosure illustrates an example in which a fourth conductive wire array 291, a fifth conductive wire array 292, and a sixth conductive wire array 293 are used such that the substrate pad array 221 is connected to the first die pad array 261 via the third die pad arrays 263A, 263B, when targeted signal transmission quality cannot be achieved by the configuration shown in FIG. 10.

The semiconductor package 200B according to FIG. 11 facilitates stacking of the plurality of semiconductor dies 230, 240, 250, and 260 on the substrate 220 without exposing the first die pad arrays to the external environment, thereby reducing the package size and preventing signal quality degradation.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor package comprising:
a substrate on which a first substrate pad array and a second substrate pad array are formed; and
a plurality of semiconductor dies each including a first die pad array and a second die pad array, the plurality of semiconductor dies stacked on the substrate in a stack;
wherein a first semiconductor die of the plurality of semiconductor dies is stacked such that the first die pad array and the second die pad array of the first semiconductor die face the first substrate pad array and the second substrate pad array, respectively, and the semiconductor dies, except for the first semiconductor die, are stacked in an orientation opposite to an orientation of the first semiconductor die.

2. The semiconductor package of claim 1, wherein the first substrate pad array is electrically connected to the first die pad array of the first semiconductor die through a first bump array.

3. The semiconductor package of claim 2, wherein the second substrate pad array is electrically connected to the second die pad array of the first semiconductor die through a second bump array.

4. The semiconductor package of claim 1, wherein each of the first die pad arrays is formed at a first distance from a center of a corresponding semiconductor die in an outward direction from the center, and the second die pad array is formed at a second distance from the first die pad array in the outward direction.

5. The semiconductor package of claim 1, wherein the second die pad arrays of the semiconductor dies, except for the first semiconductor die, are electrically connected to the second substrate pad array of the substrate through conductive wires.

6. The semiconductor package of claim 1, wherein the first semiconductor die is configured to operate as a master, and the semiconductor dies, except for the first semiconductor die, are configured to operate as slaves.

7. The semiconductor package of claim 1, wherein each of the plurality of semiconductor dies is configured to operate as a master or a slave depending on position in the stack, and master identification signals of a semiconductor die configured to operate as the master and a semiconductor die configured to operate as the slave are at different logic levels.

8. The semiconductor package of claim 1, wherein the plurality of semiconductor dies each include a switching circuit configured to change a sequence of signals transmitted between the first die pad array and the second die pad array according to a master identification signal.

9. The semiconductor package of claim 8, wherein the switching circuit comprises:
a first switching circuit configured to multiplex signals transmitted through the first die pad array according to the master identification signal; and
a second switching circuit configured to multiplex signals transmitted through the second die pad array according to the master identification signal.

10. The semiconductor package of claim 9, wherein the first switching circuit is configured to change and output the sequence of signals transmitted through pads of the first die pad array when the master identification signal is at a logic level indicating a master, and configured to output the signals transmitted through the pads of the first die pad array without changing the sequence when the master identification signal is at a logic level indicating a slave.

11. The semiconductor package of claim 1, wherein each of the plurality of semiconductor dies comprises:
a switching circuit configured to change a sequence of signals transmitted between the first die pad array and the second die pad array according to a plurality of control signals and a master identification signal; and
a control circuit configured to set the master identification signal according to stacking position information and configured to generate the plurality of control signals according to the master identification signal.

12. A semiconductor package comprising:
a substrate including a first substrate pad array and a second substrate pad array;
a first semiconductor die having a first surface on which a first die pad array and a second die pad array are formed, the first die pad array electrically connected to the first substrate pad array through a first bump array, and the second die pad array electrically connected to the second substrate pad array through a second bump array;
a second semiconductor die having a first surface on which a first die pad array and a second die pad array are formed, the second semiconductor die stacked on the first semiconductor die such that a second surface of the second semiconductor die faces a second surface of the first semiconductor die;
a third semiconductor die having a first surface on which a first die pad array and a second die pad array are formed, the third semiconductor die stacked on the second semiconductor die such that a second surface of the third semiconductor die faces the first surface of the second semiconductor die; and
a plurality of conductive wires configured to electrically connect the second die pad array of the second semiconductor die, the second die pad array of the third semiconductor die, and the second substrate pad array.

13. The semiconductor package of claim 12, wherein each of the first die pad arrays is formed at a first distance from a center of a corresponding semiconductor die in an outward direction from the center, and the second die pad array is formed at a second distance from the first die pad array in the outward direction.

14. The semiconductor package of claim 12, wherein the first semiconductor die operates as a master when a master identification signal is at a first logic level, and the second semiconductor die and the third semiconductor die operate as slaves when the master identification signal is at a second logic level.

15. The semiconductor package of claim 12, wherein the first semiconductor die, the second semiconductor die, and the third semiconductor die each include a switching circuit configured to change a sequence of signals transmitted between a corresponding first die pad array and a corresponding second die pad array according to a master identification signal.

16. The semiconductor package of claim 15, wherein the switching circuit comprises:
a first switching circuit configured to multiplex signals transmitted through the corresponding first die pad array according to the master identification signal; and
a second switching circuit configured to multiplex signals transmitted through the corresponding second die pad array according to the master identification signal.

17. The semiconductor package of claim 12, wherein each of the first semiconductor die, the second semiconductor die, and the third semiconductor die comprises:
a switching circuit configured to change a sequence of signals transmitted between a corresponding first die pad array and a corresponding second die pad array according to a plurality of control signals and a master identification signal; and
a control circuit configured to set the master identification signal according to stacking position information and configured to generate the plurality of control signals according to the master identification signal.

18. A semiconductor package comprising:
a substrate on which a substrate pad array is formed;
a plurality of semiconductor dies stacked on the substrate, each semiconductor die formed having a first die pad array, a second die pad array, and at least one third die pad array; and
a plurality of conductive wires configured to electrically connect the substrate pad array, at least one third die pad array of a second semiconductor die of the plurality of semiconductor dies, and the first die pad array of the second semiconductor die.

19. The semiconductor package of claim 18, further comprising a plurality of conductive wires configured to electrically connect the second die pad arrays of the plurality of semiconductor dies.

20. The semiconductor package of claim 18, wherein the substrate pad array is formed at a periphery of the substrate in a first direction.

21. The semiconductor package of claim 18, wherein the first die pad array is formed at a periphery in a second direction, the second die pad array is formed in the second direction at a first distance from the first die pad array, and the at least one third die pad array is formed in a first direction at a second distance from the first die pad array.

22. The semiconductor package of claim 18, wherein the second semiconductor die among the plurality of semiconductor dies is configured to operate as a master, and the semiconductor dies except for the second semiconductor die, are configured to operate as slaves.
